(19) United States
(12) Patent Application Publication
(10) Pub. No.: US 2025/0280646 A1
(43) Pub. Date: Sep. 4, 2025

(54) TRANSPARENT STRUCTURE ON pcLED TO INCREASE LIGHT FLUX

(71) Applicant: LUMILEDS LLC, San Jose, CA (US)

(72) Inventors: Sudipta Romen BISWAS, Santa Clara, CA (US); Yu-Chen SHEN, Sunnyvale, CA (US)

(73) Assignee: LUMILEDS LLC, San Jose, CA (US)

(21) Appl. No.: 19/211,391

(22) Filed: May 19, 2025

Related U.S. Application Data
(63) Continuation of application No. PCT/US2023/080707, filed on Nov. 21, 2023.
(60) Provisional application No. 63/432,521, filed on Dec. 14, 2022.

(51) Int. Cl. H10H 29/855; H10H 29/851

(52) U.S. Cl. CPC H10H 29/855; H10H 29/8512; H10H 29/8514

(57) ABSTRACT

A transparent structure attached to a phosphor-converted LED (pcLED) is disclosed. The transparent structure increases total light output of the pcLED without further increasing the light emitting area of the phosphor layer which becomes challenging and unreliable for thin phosphor layers.

### CROSS REFERENCE TO RELATED APPLICATIONS

This application is a continuation of International Patent Application No. PCT/US2023/080707 filed Nov. 21, 2023, which claims benefit of priority to U.S. Provisional Patent Application No. 63/432,521 filed Dec. 14, 2022. The foregoing applications are incorporated herein by reference in their entirety.

### FIELD OF THE INVENTION

The invention relates generally to LEDs, pcLEDs, light sources comprising LEDs, pcLEDs, and automotive lights comprising LEDs.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED.

Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Inorganic LEDs and pcLEDs have been widely used to create different types of displays, matrices and light engines including automotive adaptive headlights, augmented-reality (AR) displays, virtual-reality (VR) displays, mixed-reality (MR) displays (AR, VR, and MR systems referred to herein as visualization systems), smart glasses and displays for mobile phones, smart watches, monitors and TVs, and flash illumination for cameras in mobile phones. Individual LEDs or pcLEDs in these architectures can have an area of a few square millimeters down to a few square micrometers (e.g., microLEDs) depending on the matrix or display sized and its pixel per inch requirements.

### SUMMARY

This specification discloses a phosphor-converted LED having an LED die, a wavelength converting structure disposed on the LED die, and a transparent structure disposed on the wavelength converting structure. The wavelength converting structure has a thickness of less than 110 μm and has an overhang portion that hangs over the substrate to which the LED die is mounted on. The transparent structure has a height ranging from 10 μm to 500 μm. The transparent structure increases the total light flux emitted from the pcLED as compared to a pcLED without the transparent structure.

In some embodiments the transparent structure has a base surface and a light emitting surface that are substantially parallel. In some embodiments, the sidewalls connecting the base surface and the light emitting surface are planar. In other embodiments, the sidewalls are curved. In other embodiments, the sidewalls have a corrugated shape. In some embodiments, the light emitting surface of the transparent structure is textured. In some embodiments, the base surface of the transparent structure is textured.

In some embodiments, the base surface of the transparent structure is greater than the light emitting area of the wavelength converting structure thereby creating an overhang distance between an edge of the base surface and an edge of the light emitting surface of the wavelength converting structure. This overhang distance ranges range 0 μm to 500 μm. In some embodiments, the overhang distance is less than 300 μm. In some embodiments, there exists more than one overhang distances between the edges of the base surface and edges of the light emitting surface of the wavelength converting structure. In some embodiments, the overhang distance in a first direction ranges range 0 μm to 500 μm while the overhang distance in a perpendicular second direction is 0 μm. In some embodiments, the overhang distance in a first direction and overhang distance in a perpendicular second direction are different.

In some embodiments, the transparent structure is in the shape of a pyramidal frustum. The angle θ between the sidewall of the frustum and the height of the frustum ranges from greater than 10° to less than 75°. In some embodiments, angle θ is approximately 45°.

The transparent structure is made from a transparent material having an index of refraction less than an index of refraction of the wavelength converting structure and greater than 1. In some embodiments, the transparent material is glass. In other embodiments, the transparent material is silicone.

The pcLED disclosed herein may be used for example in the various devices and applications listed above in the Background section. In particular, the pcLED disclosed herein may be used in automotive lighting applications where increases in total light flux is beneficial. For example, the pcLED disclosed herein may be used in headlights, taillights, turn indicator lights, and vehicle interior lamination and indictor lights.

These and other embodiments, features and advantages of the present invention will become more apparent to those skilled in the art when taken with reference to the following more detailed description of the invention in conjunction with the accompanying drawings that are first briefly described

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3 shows a schematic top view of an electronics board on which an array of LEDs or pcLEDs may be mounted, and FIG. 4 similarly shows an array of pcLEDs mounted on the electronic board of FIG. 3.

FIG. 5 schematically illustrates an example camera flash system.

FIG. 6 schematically illustrates an example display system.

FIG. 7 shows a block diagram of an example visualization system.

FIG. 8 shows a schematic cross-sectional view of an example pcLED.

FIGS. 9, 10, and 11 show a schematic cross-sectional views of example pcLEDs with a transparent structure.

FIGS. 12 and 13 show a schematic plan views of example pcLEDs with a transparent structure.

FIGS. 14, 15, 16, 17, 18, and 19 show simulation results done using design of experiments (DOE) in JMP software.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual pcLED 100 comprising a light emitting semiconductor diode (LED) structure 102 disposed on a substrate 104, and a phosphor layer 106 (which may also be referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. Phosphor layers may for example comprise phosphor particles dispersed in or bound to each other with a binder material or be or comprise a sintered ceramic phosphor plate.

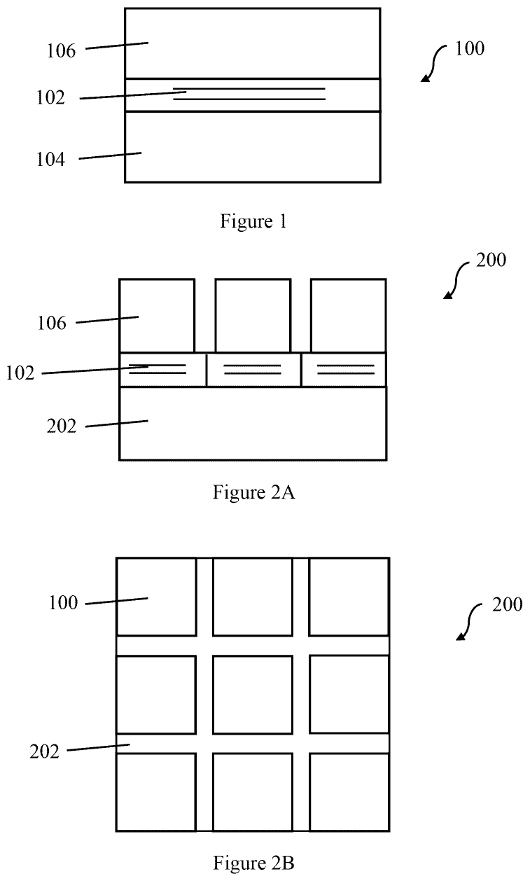

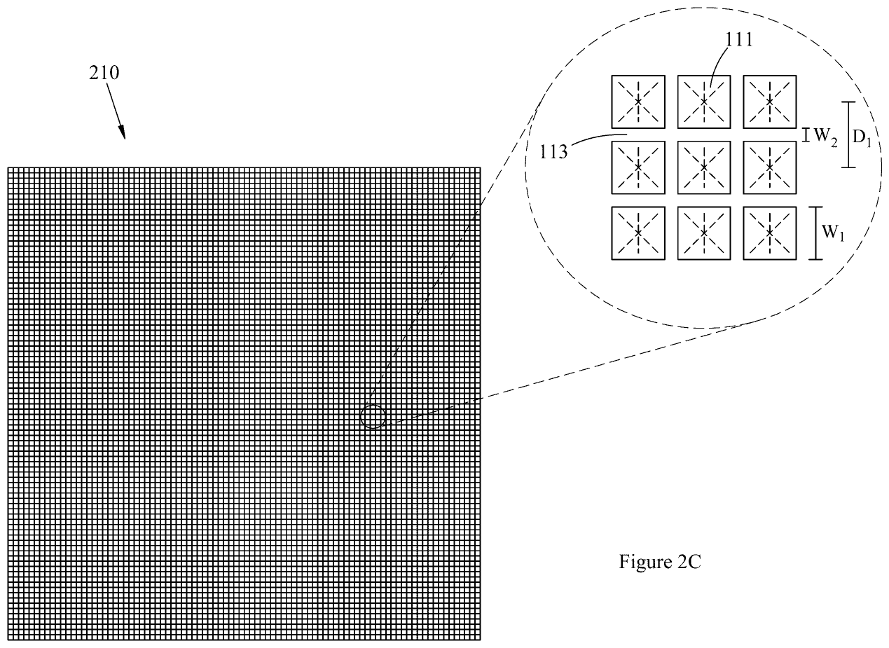

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of LEDs or pcLEDs may be formed from individual mechanically separate LEDs or pcLEDs. Substrate 202 may optionally comprise CMOS circuitry for driving the LEDs and may be formed from any suitable materials.

Although FIGS. 2A-2B show a three-by-three array of nine pcLEDs, such arrays may include for example tens, hundreds, or thousands of LEDs or pcLEDs. Individual LEDs or pcLEDs may have widths (e.g., side lengths) in the plane of the array of, for example, less than or equal to 2 millimeters (mm), less than or equal to 1 mm, less than or equal to 500 microns, less than or equal to 100 microns, less than or equal to 50 microns, or less than or equal to 10 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W₁ are arranged as a square matrix with neighboring LEDs or pcLEDs having a center-to-center distances D₁ and separated by lanes 113 having a width W₂. W₁ may be, for example, less than or equal to 2 mm, less than or equal to 1 mm, less than or equal to 500 microns, less than or equal to 100 microns, less than or equal to 50 microns, or less than or equal to 10 microns. W₂ may be, for example, hundreds of microns, less than or equal to 100 microns, less than or equal to 50 microns, less than or equal to 10 microns, or less than or equal to 5 microns. D₁=W₁+W₂.

An array may be formed, for example, by dicing wafer 210 into individual LEDs or pcLEDs and arranging the dice on a substrate. Alternatively, an array may be formed from the entire wafer 210, or by dividing wafer 210 into smaller arrays of LEDs or pcLEDs.

LEDs or pcLEDs having dimensions in the plane of the array (e.g., side lengths) of less than or equal to about 50 microns are typically referred to as microLEDs, and an array of such microLEDs may be referred to as a microLED array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated or partially electrically isolated from each other by trenches and/or insulating material, but the electrically isolated or partially electrically isolated segments remain physically connected to each other by other portions of the semiconductor structure. For example, in such a monolithic structure the active region and a first semiconductor layer of a first conductivity type (n or p) on one side of the active region may be segmented, and a second unsegmented semiconductor layer of the opposite conductivity type (p or n) positioned on the opposite side of the active region from the first semiconductor layer. The second semiconductor layer may then physically and electrically connect the segmented structures to each other on one side of the active region, with the segmented structures otherwise electrically isolated from each other and thus separately operable as individual LEDs.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

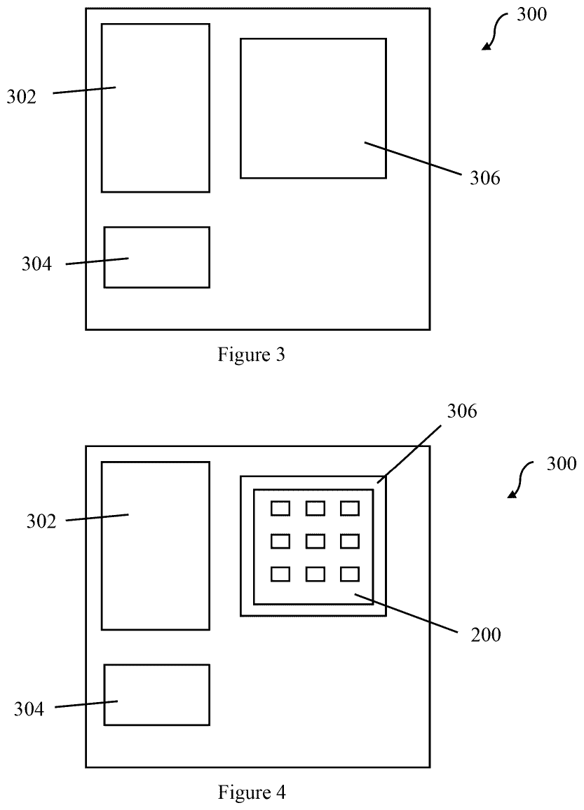

As shown in FIGS. 3 & 4, an LED or pcLED array 200 may for example be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

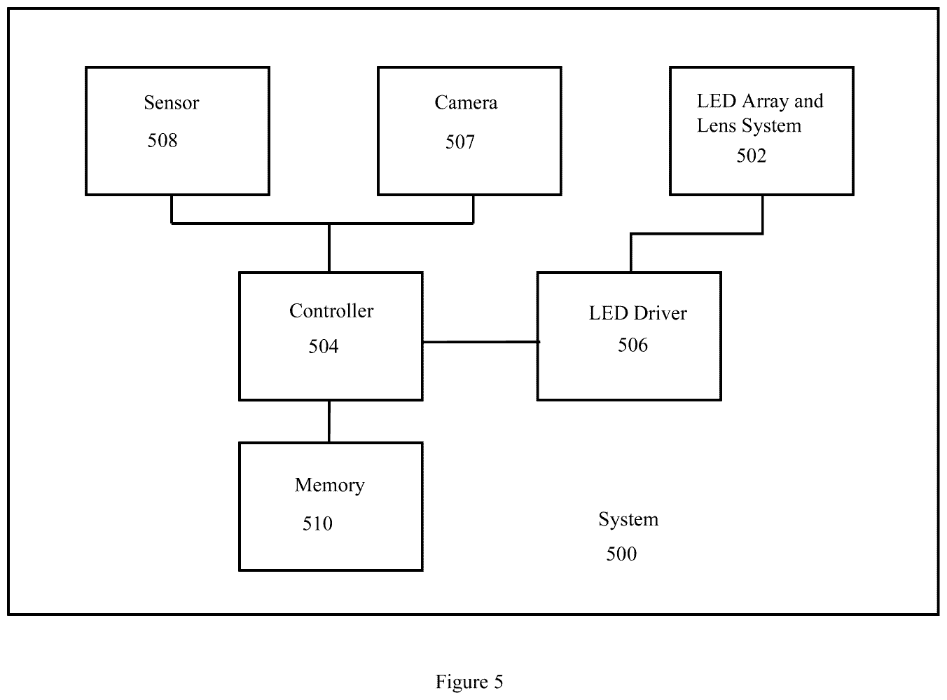

FIG. 5 schematically illustrates an example camera flash system 500 comprising an LED or pcLED array and an optical (e.g., lens) system 502, which may be or comprise an adaptive lighting system as described above in which LEDs or pcLEDs in the array may be individually operable or operable as groups. In operation of the camera flash system, illumination from some or all of the LEDs or pcLEDs in array and optical system 502 may be adjusted-deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

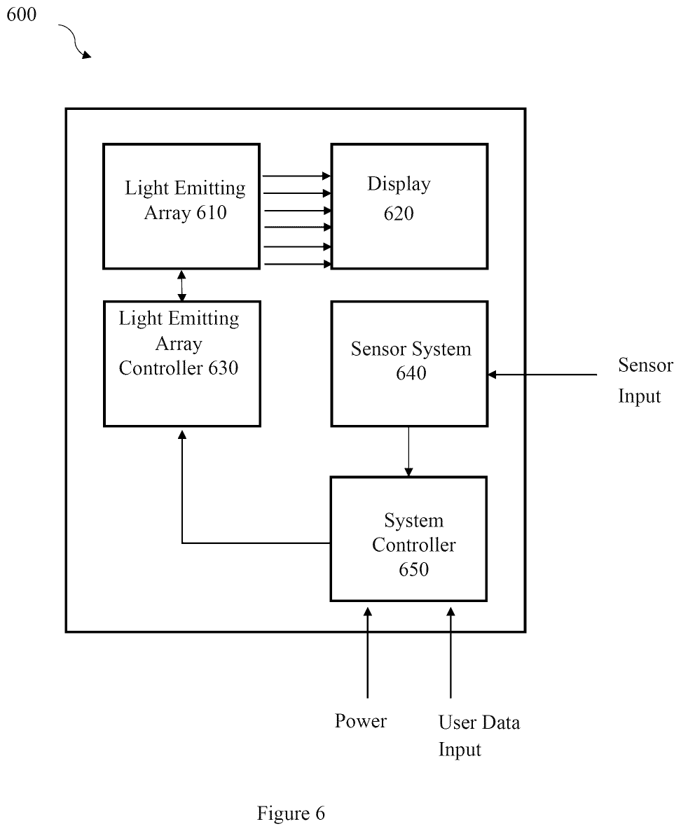

FIG. 6 schematically illustrates an example display system 600 that includes an array 610 of LEDs or pcLEDs that are individually operable or operable in groups, a display 620, a light emitting array controller 630, a sensor system 640, and a system controller 650. Array 610 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Similarly, to provide redundancy in the event of a defective LED or pcLED, a group of six individually operable adjacent LEDs or pcLEDs comprising two red emitters, two blue emitters, and two green emitters may correspond to a single color-tunable pixel in the display Array 610 can be used to project light in graphical or object patterns that can for example support AR/VR/MR systems.

Sensor input is provided to the sensor system 640, while power and user data input is provided to the system controller 650. In some embodiments modules included in system 600 can be compactly arranged in a single structure, or one or more elements can be separately mounted and connected via wireless or wired communication. For example, array 610, display 620, and sensor system 640 can be mounted on a headset or glasses, with the light emitting array controller and/or system controller 650 separately mounted.

System 600 can incorporate a wide range of optics (not shown) to couple light emitted by array 610 into display 620. Any suitable optics may be used for this purpose.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input through the sensor system can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

As noted above, AR, VR, and MR systems may be more generally referred to as examples of visualization systems. In a virtual reality system, a display can present to a user a view of a scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

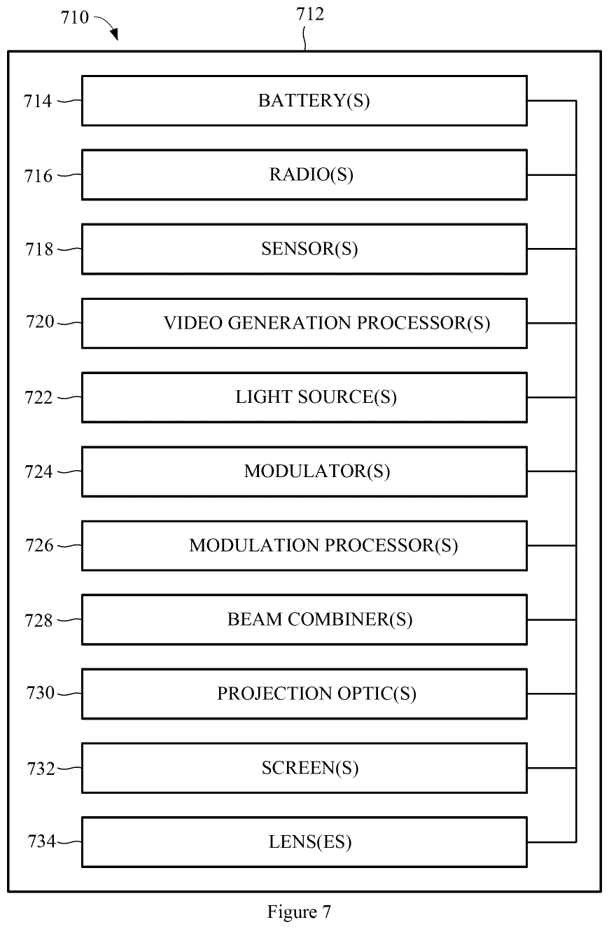

FIG. 7 shows a generalized block diagram of an example visualization system 710. The visualization system 710 can include a wearable housing 712, such as a headset or goggles. The housing 712 can mechanically support and house the elements detailed below. In some examples, one or more of the elements detailed below can be included in one or more additional housings that can be separate from the wearable housing 712 and couplable to the wearable housing 712 wirelessly and/or via a wired connection. For example, a separate housing can reduce the weight of wearable goggles, such as by including batteries, radios, and other elements. The housing 712 can include one or more batteries 714, which can electrically power any or all of the elements detailed below. The housing 712 can include circuitry that can electrically couple to an external power supply, such as a wall outlet, to recharge the batteries 714. The housing 712 can include one or more radios 716 to communicate wirelessly with a server or network via a suitable protocol, such as WiFi.

The visualization system 710 can include one or more sensors 718, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 718 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 718 can capture a real-time video image of the surroundings proximate a user.

The visualization system 710 can include one or more video generation processors 720. The one or more video generation processors 720 can receive, from a server and/or a storage medium, scene data that represents a three-dimensional scene, such as a set of position coordinates for objects in the scene or a depth map of the scene. The one or more video generation processors 720 can receive one or more sensor signals from the one or more sensors 718. In response to the scene data, which represents the surroundings, and at least one sensor signal, which represents the location and/or orientation of the user with respect to the surroundings, the one or more video generation processors 720 can generate at least one video signal that corresponds to a view of the scene. In some examples, the one or more video generation processors 720 can generate two video signals, one for each eye of the user, that represent a view of the scene from a point of view of the left eye and the right eye of the user, respectively. In some examples, the one or more video generation processors 720 can generate more than two video signals and combine the video signals to provide one video signal for both eyes, two video signals for the two eyes, or other combinations.

The visualization system 710 can include one or more light sources 722 that can provide light for a display of the visualization system 710. Suitable light sources 722 can include any of the LEDs, pcLEDs, LED arrays, and pcLED arrays discussed above, for example those discussed above with respect to display system 600. The visualization system 710 can include one or more modulators 724. The modulators 724 can be implemented in one of at least two configurations.

In a first configuration, the modulators 724 can include circuitry that can modulate the light sources 722 directly. For example, the light sources 722 can include an array of light-emitting diodes, and the modulators 724 can directly modulate the electrical power, electrical voltage, and/or electrical current directed to each light-emitting diode in the array to form modulated light. The modulation can be performed in an analog manner and/or a digital manner. In some examples, the light sources 722 can include an array of red light-emitting diodes, an array of green light-emitting diodes, and an array of blue light-emitting diodes, and the modulators 724 can directly modulate the red light-emitting diodes, the green light-emitting diodes, and the blue light-emitting diodes to form the modulated light to produce a specified image.

In a second configuration, the modulators 724 can include a modulation panel, such as a liquid crystal panel. The light sources 722 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 724 can include multiple modulation panels that can modulate different colors of light. For example, the modulators 724 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 724 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 710 can include one or more modulation processors 726, which can receive a video signal, such as from the one or more video generation processors 720, and, in response, can produce an electrical modulation signal. For configurations in which the modulators 724 directly modulate the light sources 722, the electrical modulation signal can drive the light sources 724. For configurations in which the modulators 724 include a modulation panel, the electrical modulation signal can drive the modulation panel.

The visualization system 710 can include one or more beam combiners 728 (also known as beam splitters 728), which can combine light beams of different colors to form a single multi-color beam. For configurations in which the light sources 722 can include multiple light-emitting diodes of different colors, the visualization system 710 can include one or more wavelength-sensitive (e.g., dichroic) beam splitters 728 that can combine the light of different colors to form a single multi-color beam.

The visualization system 710 can direct the modulated light toward the eyes of the viewer in one of at least two configurations. In a first configuration, the visualization system 710 can function as a projector, and can include suitable projection optics 730 that can project the modulated light onto one or more screens 732. The screens 732 can be located a suitable distance from an eye of the user. The visualization system 710 can optionally include one or more lenses 734 that can locate a virtual image of a screen 732 at a suitable distance from the eye, such as a close-focus distance, such as 500 mm, 750 mm, or another suitable distance. In some examples, the visualization system 710 can include a single screen 732, such that the modulated light can be directed toward both eyes of the user. In some examples, the visualization system 710 can include two screens 732, such that the modulated light from each screen 732 can be directed toward a respective eye of the user. In some examples, the visualization system 710 can include more than two screens 732. In a second configuration, the visualization system 710 can direct the modulated light directly into one or both eyes of a viewer. For example, the projection optics 730 can form an image on a retina of an eye of the user, or an image on each retina of the two eyes of the user.

For some configurations of augmented reality systems, the visualization system 710 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

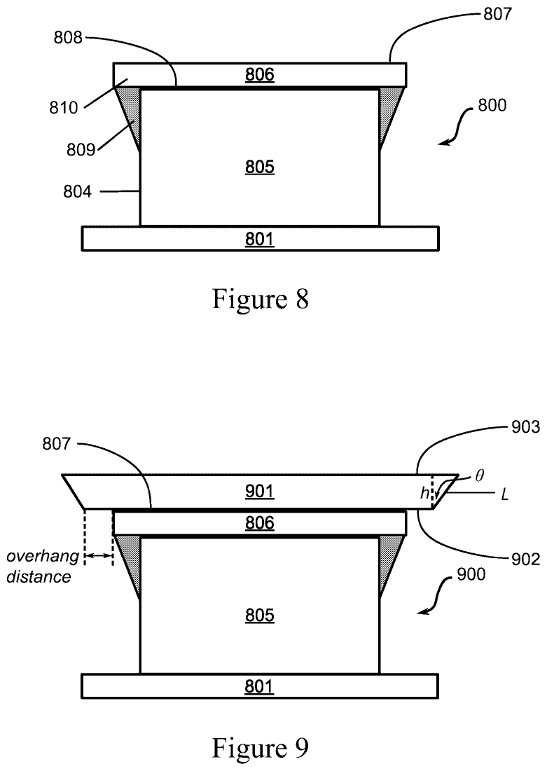

In many systems, an increase in the total light output (“total LOP”) of LED, pcLEDs, LED arrays, or pcLED arrays is desirable. Systems that may benefit from an increase in total LOP include automotive lighting, including headlights, taillights, signal indicators, display lights within the automobile, camera flash, etc. One way to increase the total LOP of an LED is to increase the light emitting area (“LEA”) of the phosphor layer, i.e. a wavelength converting structure containing phosphor material. For pcLEDs, total LOP is proportional to the size of the wavelength converting structure. FIG. 8 shows wavelength converting structure 806 disposed on LED die 805, which comprises the semiconductor diode structure. LED die 805 is disposed on substrate 801. Wavelength converting structure 806 is attached to LED die 805 using a transparent glue 809. In FIG. 8, the LEA 807 of the wavelength converting structure is greater than the LEA 808 of the LED die. This arrangement increases the total LOP of pcLED 800 as compared to the arrangement pcLED 100 shown in FIG. 1.

But there is a limit to how much greater LEA 807 of the wavelength converting structure can be increased particularly if the wavelength converting structure is thin, i.e. less than 110 μm thick. This is for example due to the overhang portion 810 created by having the surface area of the wavelength converting structure in contact with LED die 805 be greater than the LEA 808 of LED die 805. The overhang portion 810 of wavelength converting structure 806 is a projection of wavelength converting structure 806 beyond sidewall 804 of LED die 805 so that overhang portion 810 hangs over substrate 801. Increasing the LEA of the wavelength converting structure by increasing structure overhang 810 becomes challenging and unreliable for thin wavelength converting structures (less than about 100 μm) as the structure might crack since there is not enough support underneath overhang 810.

To further increase the total LOP of a pcLED where the wavelength converting structure is less than 110 μm thick, a transparent structure generally in the shape of a frustum is disposed on top of the wavelength converting structure, which helps extract more light from the pcLED while increasing the top LEA. The transparent structure is made of a transparent material that has an index of refraction less than the index of refraction of the phosphor layer but greater than the index of refraction of air, i.e. greater than 1. In some embodiments, the transparent structure of made of glass. In other embodiments, the transparent structure of made of silicone. The transparent structure may be attached to wavelength converting structure by a transparent glue such as silicone epoxy or silicone resin.

In FIG. 9, transparent structure 901 is disposed onto wavelength converting structure 806 to form pcLED 900. Transparent structure 901 in FIG. 9 is in the shape of a pyramidal frustum with base 902 facing and in contact with phosphor layer 806 and base 903 being the light emitting area of the pcLED. Base 903 is substantially parallel to base 902. Transparent structure 901 has a height, h, between the bases 902 and 903 and angle, θ, between height, h, and slant height, L. The area of base 903 is larger than the area of base 902. In some embodiments, the area of base 902 may be larger than LEA 807 of wavelength converting structure 806, which creates an overhang distance between the edge of base 902 and the edge of LEA 807. The portion of transparent structure 901 covered by the overhang distance hangs over substrate 801. In some embodiments, nothing supports transparent structure 901 underneath the portion of the transparent structure between the edge of base 902 and the edge of LEA 807. In some embodiments, base 902 has a textured surface. In some embodiments, base 903 has a textured surface. Textured surfaces help extract more light from the pcLED. In some embodiments, the surfaces of both base 902 and base 903 are textured. Height h may be between 10 μm and 500 μm. The angle θ may be between 10° and 75°. The overhang distance may be between 0 μm to 300 μm. In some embodiments, the overhang distance may be between 0 μm to 500 μm.

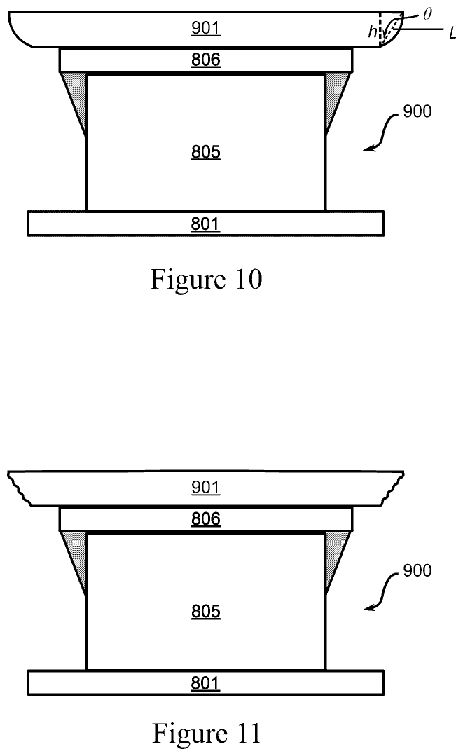

FIG. 10 shows an alternate embodiment of transparent structure 901 where the sidewalls of the transparent structure are curved instead of straight. In some embodiments, the shape of the curve may be circular. In some embodiments, the shape of the curve may be parabolic. The shape of the curve may be configured to direct light out through the LEA of the transparent structure.

FIG. 11 shows an alternate embodiment of transparent structure 901 where the sidewalls of the transparent structure are corrugated, i.e. the sidewalls have ridges or grooves or both. In some embodiments, the sidewalls may be corrugated in the shape of a sine wave. In some embodiments, the sidewalls may have a sawtooth corrugated shape.

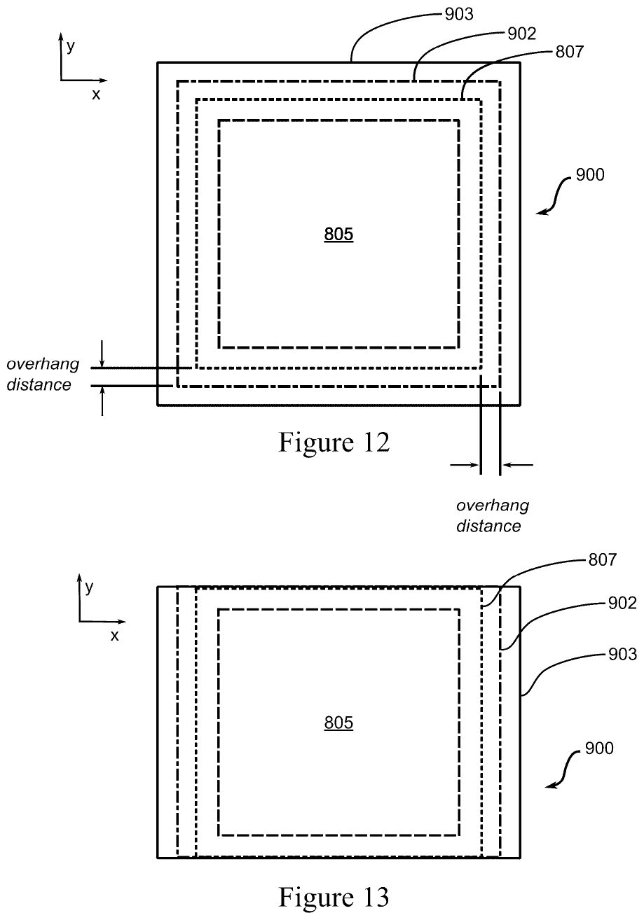

Transparent structure 901 may disposed onto wavelength converting structure 806 in a symmetric manner. FIG. 12 shows a plan view of pcLED 900 of FIGS. 9-11. As shown in FIG. 12, the transparent structure is disposed onto the wavelength converting structure in a symmetric manner so that the overhang distance between LEA 807 of the wavelength converting structure and base 902 of the transparent structure is equal on all four sides of pcLED 900. Specifically, the two overhang distances in the x direction, as shown in FIG. 12, are equal and equal to the two overhang distances in the y direction. In addition, angle θ is equal in all four directions, i.e. the positive and negative x direction and the positive and negative y direction.

FIG. 13 shows a plan view of pcLED 900 of FIGS. 9-11 where the overhang distance and angle θ are not equal in the x and y directions. In FIG. 13, there is a certain positive overhang distance in the positive and negative x directions, but there is no overhang distance in the positive and negative y directions. In some embodiments, the positive and negative x direction overhang distances are equal. In addition, the transparent structure in FIG. 13 has a certain angle θ in the positive and negative x directions, but no angle θ in the positive and negative y directions, i.e. angle θ is substantially zero in those directions. The effect of having a certain overhang distance and angle θ in the x directions but not in the y directions is pcLED 900 will emit more light in the x directions than in the y directions. Having an overhang distance and an angle θ increases the light flux emitted in those directions.

Simulations have shown about a 5-10% increase in total flux by using the transparent structure disclosed in this specification compared with a pcLED without a transparent structure. The simulations were done using design of experiments (DOE) in JMP with 3 parameters for the transparent structure: height h, angle θ, and overhang distance. In the simulations, h was allowed to range from 50 to 500 μm, angle θ was allowed to range from 10° to 75°, and overhang distance was allowed to range from 0 to 200 μm. These parameters were optimized with the help of desirability profiler in JMP. The simulations assume that angle θ and the overhang distance are equal in all four directions, i.e. in the positive and negative for the x and y directions.

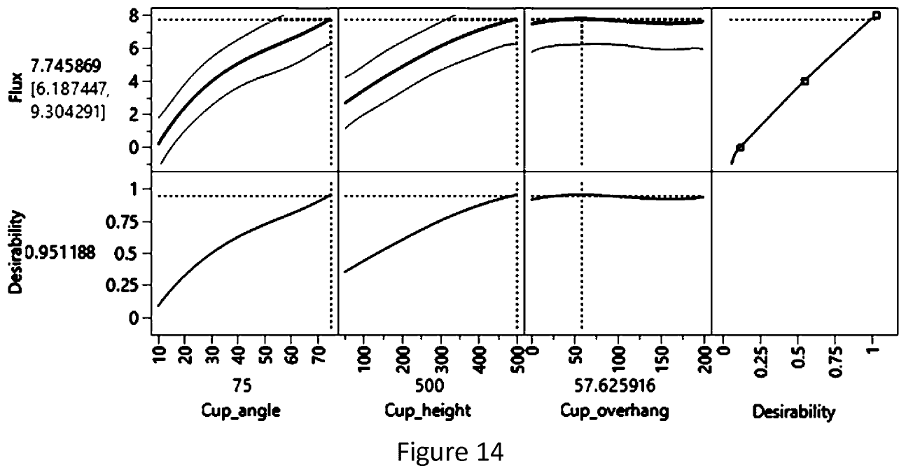

FIG. 14 shows the simulation results for a 1 mm² LED die a 1.06×1.06 mm² wavelength converting structure, i.e. a LED die with a LEA of 1 mm² and a wavelength converting structure with a LEA of 1.06 mm². In this LED and wavelength converting structure configuration, FIG. 14 shows that the optimal angle θ is 75°, the optimal height is 500 μm, and the optimal overhang distance about 58 μm. With these optimized parameters, the transparent structure is predicted to increase the total light flux of the pcLED by about 7.7% as compared with a pcLED without the transparent structure with a prediction confidence interval of between about 6.2% to about 9.3% increase in total flux. The shaded area in the graphs shown in FIGS. 14-19 represents the confidence interval. Desirability in FIGS. 14-19 is a function used by the desirability profiler of JMP to aid in optimization.

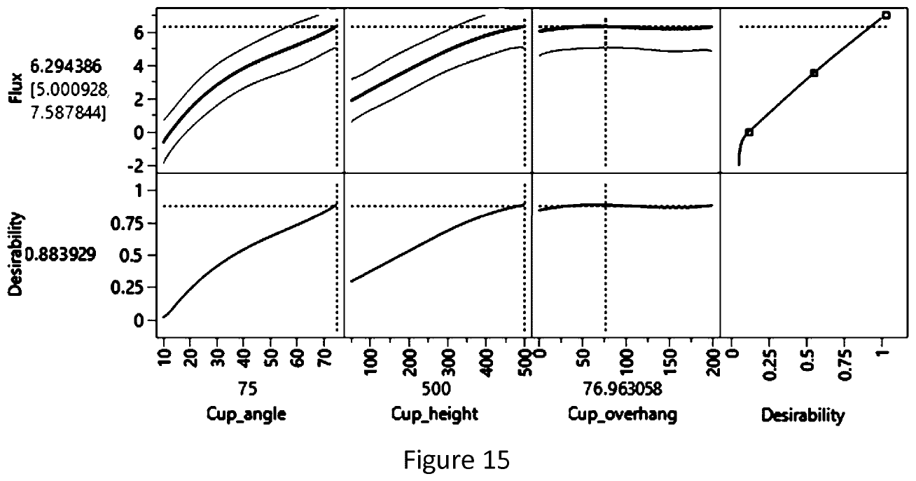

FIG. 15 shows simulation results for a 1 mm² LED die with a 1.15×1.15 mm² wavelength converting structure. LED and wavelength converting structure configuration, the optimal angle θ is 75°, the optimal height is 500 μm, and the optimal overhang distance about 77 μm. With these optimized parameters, the transparent structure is predicted to increase the total light flux of the pcLED by about 6.3%, with of confidence interval between about 5% and 7.6%, as compared with a pcLED without the transparent structure.

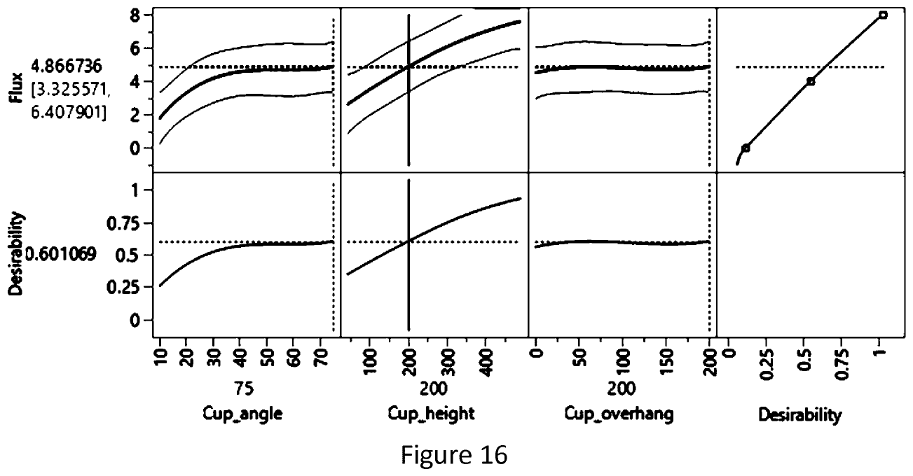

FIG. 16 shows simulation results for a 1 mm² LED die a 1.06×1.06 mm² wavelength converting structure where the height of the transparent structure fixed at 200 μm. With h fixed at 200 μm, the optimal angle θ is 75° and the optimal overhang distance about 200 μm. With these optimized parameters, the transparent structure is predicted to increase the total light flux of the pcLED by about 4.9%, with of confidence interval between about 3.3% and 6.4%, as compared with a pcLED without the transparent structure.

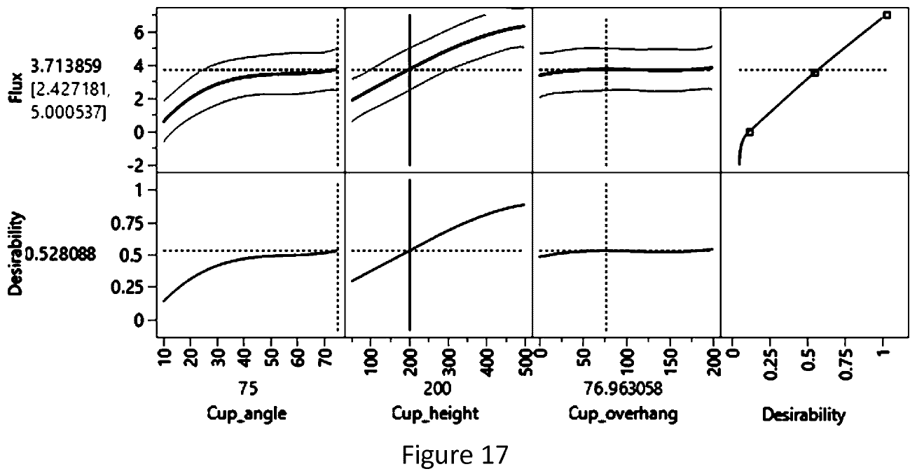

FIG. 17 shows simulation results for a 1 mm² LED die with a 1.15×1.15 mm² wavelength converting structure where the height of the transparent structure fixed at 200 μm. With h fixed at 200 μm, the optimal angle θ is 75° and the optimal overhang distance about 77 μm. With these optimized parameters, the transparent structure is predicted to increase the total light flux of the pcLED by about 3.7%, with of confidence interval between about 2.4% and 5%, as compared with a pcLED without the transparent structure.

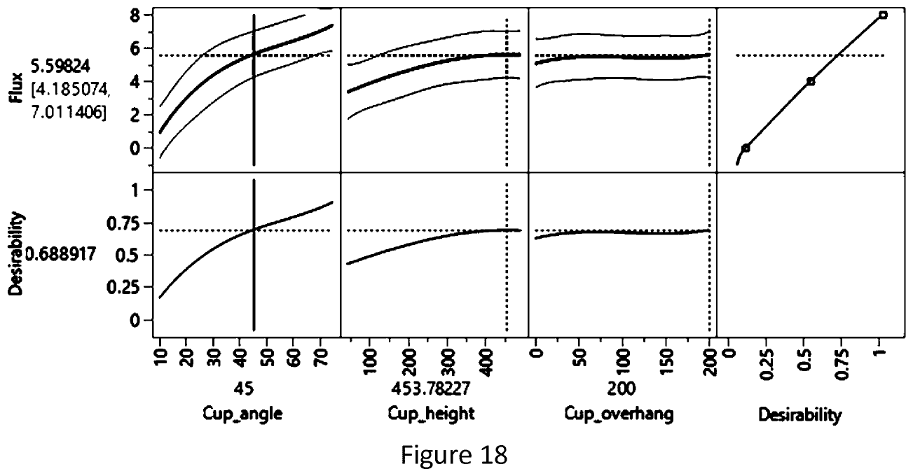

FIG. 18 shows simulation results for a 1 mm² LED die with a 1.06×1.06 mm² wavelength converting structure where angle θ of the transparent structure fixed at about 45°. With angle θ=45°, the optimal height is about 454 μm and the optimal overhang distance about 200 μm. With these optimized parameters, the transparent structure is predicted to increase the total light flux of the pcLED by about 5.5%, with of confidence interval between about 4.2% and 7%, as compared with a pcLED without the transparent structure.

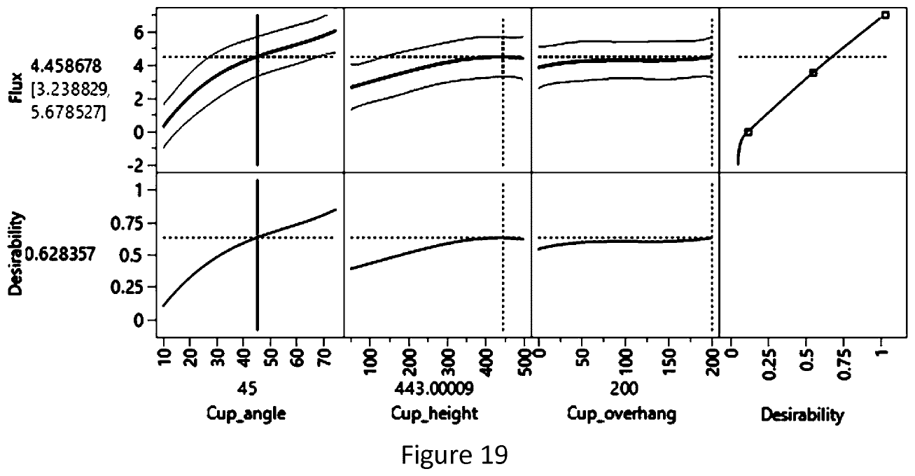

FIG. 19 shows simulation results for a 1 mm² LED die with a 1.15×1.15 mm² wavelength converting structure where angle θ of the transparent structure fixed at 45°. With angle θ=45°, the optimal height is about 443 μm and the optimal overhang distance about 200 μm. With these optimized parameters, the transparent structure is predicted to increase the total light flux of the pcLED by about 4.4%, with of confidence interval between about 3.2% and 5.7%, as compared with a pcLED without the transparent structure.

This disclosure is illustrative and not limiting. Further modifications will be apparent to one skilled in the art in light of this disclosure and are intended to fall within the scope of the appended claims.

What is claimed is:

1. A pcLED comprising:
an LED die comprising a light emitting surface having a first area;
a wavelength converting structure comprising a phosphor and a light emitting surface having a second area greater than the first area, the wavelength converting structure disposed on the light emitting surface of the LED die, the wavelength converting structure having a thickness less than 110 μm; and
a transparent structure comprising
a transparent material having an index of refraction less than an index of refraction of the wavelength converting structure and greater than 1,
a flat base surface having a third area greater than the second area, the flat base surface contacting the light emitting surface of the wavelength converting structure to create an overhang distance between an edge of the flat base surface and an edge of the light emitting surface of the wavelength converting structure, and
an oppositely positioned light emitting surface having a fourth area greater than the third area and the second area,
the transparent structure having a height between the base surface and the light emitting surface of less than 500 μm.

2. The pcLED of claim 1, wherein the LED die is disposed on a substrate and the wavelength converting structure disposed on the light emitting surface of the LED die to create an overhang portion of the wavelength converting structure that hangs over the substrate.

3. The pcLED of claim 1, wherein the base surface and light emitting surface of the transparent structure are substantially parallel.

4. The pcLED of claim 1, wherein the transparent structure comprises sidewalls connecting the base surface and the light emitting surface.

5. The pcLED of claim 4, wherein the sidewalls have a corrugated shape.

6. The pcLED of claim 4, wherein the sidewalls have a curved shape.

7. The pcLED of claim 1, wherein the light emitting surface of the transparent structure is textured.

8. The pcLED of claim 1, wherein the base surface of the transparent structure is textured.

9. The pcLED of claim 1, wherein nothing supports the transparent structure underneath a portion of the transparent structure between the edge of the flat base surface of the transparent structure and the edge of the light emitting surface of the wavelength converting structure.

10. The pcLED of claim 9, wherein the overhang distance is less than 300 μm.

11. A pcLED comprising:
an LED die comprising a light emitting surface having a first area;
a wavelength converting structure comprising a phosphor and a light emitting surface having a second area greater than the first area, the wavelength converting structure disposed on the light emitting surface of the LED die, the wavelength converting structure having a thickness less than 110 μm; and
a transparent structure in the shape of a pyramidal frustum comprising
a transparent material having an index of refraction less than an index of refraction of the wavelength converting structure and greater than 1,
a flat first base surface having a third area greater than the second area, the flat first base surface contacting the light emitting surface of the wavelength converting structure to create a first overhang distance between a first edge of the flat base surface and a first edge of the light emitting surface of the wavelength converting structure, and
a second base surface having a fourth area greater than the third area and the second area,
the transparent structure having a height between the first and second base surfaces of less than 500 μm.

12. The pcLED of claim 11, wherein the LED die is disposed on a substrate and the wavelength converting structure disposed on the light emitting surface of the LED die creates an overhang portion of the wavelength converting structure that hangs over the substrate.

13. The pcLED of claim 11, wherein the second base surface of the transparent structure is textured.

14. The pcLED of claim 11, wherein a second overhang distance is created between a second edge of the flat base surface and a second edge of the light emitting surface of the wavelength converting structure, the second overhang distance not equal to the first overhang distance.

15. The pcLED of claim 11, wherein the transparent structure comprises a sidewall connecting the first and second base surfaces and an angle θ between the sidewall and the height, wherein angle θ is greater than 10° and less than 75°.

16. The pcLED of claim 15, wherein angle θ is about 45°.

17. The pcLED of claim 11, wherein transparent material is glass.

18. The pcLED of claim 11, wherein the height of the transparent structure is less than 200 μm.

19. An automobile comprising a light emitting device comprising the pcLED of claim 1.
